(19) United States
(12) Patent Application Publication
(10) Pub. No.: US 2012/0152606 A1
(43) Pub. Date: Jun. 21, 2012

(54) PRINTED WIRING BOARD

(75) Inventor: Satoshi Kurokawa, Ogaki-shi (JP)

(73) Assignee: IBIDEN CO., LTD., Ogaki-shi (JP)

(21) Appl. No.: 13/222,521

(22) Filed: Aug. 31, 2011

Related U.S. Application Data
(60) Provisional application No. 61/423,716, filed on Dec. 16, 2010.

(51) Int. Cl. H05K 1/11; H05K 3/34

(52) U.S. Cl. 174/262; 29/840

(57) ABSTRACT

A printed wiring board including an insulation layer, a conductive layer formed on the insulation layer and including a via conductor pad and a chip capacitor mounting pad, an outermost resin insulation layer formed on the insulation and conductive layers and having a via hole reaching the conductor pad and an opening exposing the mounting pad, an electrode having a via conductor portion in the hole and a land portion extending from the via conductor such that the electrode protrudes from the surface of the outermost layer, a solder bump for mounting an IC formed on the land portion such that the bump is at a portion of the electrode protruding from the surface of the outermost layer, and a solder structure for mounting a chip capacitor formed on the mounting pad such that the structure extends from the mounting pad and projects from the surface of the outermost layer.

### CROSS-REFERENCE TO RELATED APPLICATIONS

The present application claims the benefits of priority to U.S. Application No. 61/423,716, filed Dec. 16, 2010. The contents of that application are incorporated herein by reference in their entirety.

### BACKGROUND OF THE INVENTION

1. Field of the Invention

The present invention relates to a printed wiring board for mounting an IC chip and a chip capacitor.

2. Discussion of the Background

Japanese Laid-Open Patent Publication No. 2004-63904 describes a buildup multilayer wiring board without a solder-resist layer. In Japanese Laid-Open Patent Publication No. 2004-63904, the outermost buildup resin insulation layer works as a solder-resist layer, and pads as external connection terminals are formed on the outermost buildup resin insulation layer. The contents of these publications (this publication) are incorporated herein by reference in their entirety.

### SUMMARY OF THE INVENTION

According to one aspect of the present invention, a printed wiring board includes an insulation layer, a conductive layer formed on the insulation layer and including a via conductor pad and a chip capacitor mounting pad, an outermost resin insulation layer formed on the insulation layer and the conductive layer and having a via hole reaching the via conductor pad and an opening exposing the chip capacitor mounting pad, an electrode having a via conductor portion formed in the via hole in the outermost resin insulation layer and a land portion extending from the via conductor such that the electrode protrudes from a surface of the outermost resin insulation layer, a solder bump for mounting an IC formed on the land portion of the electrode such that the solder bump is positioned at a portion of the electrode protruding from the surface of the outermost resin insulation layer, and a solder structure for mounting a chip capacitor formed on the chip capacitor mounting pad such that the solder structure extends from the chip capacitor mounting pad and projects from the surface of the outermost resin insulation layer.

According to another aspect of the present invention, a method of manufacturing a printed wiring board includes forming on an insulation layer a conductive layer including a via conductor pad and a chip capacitor mounting pad, forming an outermost resin insulation layer on the insulation layer and the conductive layer, forming a via hole reaching the via conductor pad through the outermost resin insulation layer, forming an opening exposing the chip capacitor mounting pad through the outermost resin insulation layer, forming an electrode having a via conductor portion formed in the via hole in the outermost resin insulation layer and a land portion extending from the via conductor such that the electrode protrudes from a surface of the outermost resin insulation layer, forming on the land portion of the electrode a solder bump for mounting an IC such that the solder bump is positioned at a portion of the electrode protruding from the surface of the outermost resin insulation layer, and forming on the chip capacitor mounting pad a solder structure for mounting a chip capacitor such that the solder structure extends from the chip capacitor mounting pad and projects from the surface of the outermost resin insulation layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1(A)-(E) are views of steps for manufacturing a printed wiring board according to an embodiment of the present invention;

FIGS. 2(A)-(D) are views of steps for manufacturing a printed wiring board according to the embodiment of the present invention;

FIGS. 3(A)-(E) are views of steps for manufacturing a printed wiring board according to the embodiment of the present invention;

FIGS. 4(A)-(D) are views of steps for manufacturing a printed wiring board according to the embodiment of the present invention;

FIGS. 5(A)-(D) are cross-sectional views of a printed wiring board according to the embodiment of the present invention;

FIG. 6 is a cross-sectional view of a printed wiring board according to the embodiment of the present invention;

FIG. 7 is a view showing a state where chip capacitors are mounted on a printed wiring board according to the embodiment of the present invention;

FIG. 8 is a view showing a state where an IC chip is mounted on a printed wiring board according to the embodiment of the present invention;

FIG. 9(A) is a plan view of a chip capacitor, FIG. 9(B) is its side view, and FIGS. 9(C) and 9(D) are plan views of an outermost interlayer resin insulation layer;

FIGS. 10(A)-(C) are views of steps for manufacturing a printed wiring board according to another embodiment;

FIGS. 11(A)-(C) are views of steps for manufacturing a printed wiring board according to the other embodiment;

FIGS. 12(A)-(B) are views of steps for manufacturing a printed wiring board according to the other embodiment; and

FIG. 13 is a cross-sectional view showing a multilayer printed wiring board according to conventional art.

### DETAILED DESCRIPTION OF THE EMBODIMENTS

The embodiments will now be described with reference to the accompanying drawings, wherein like reference numerals designate corresponding or identical elements throughout the various drawings.

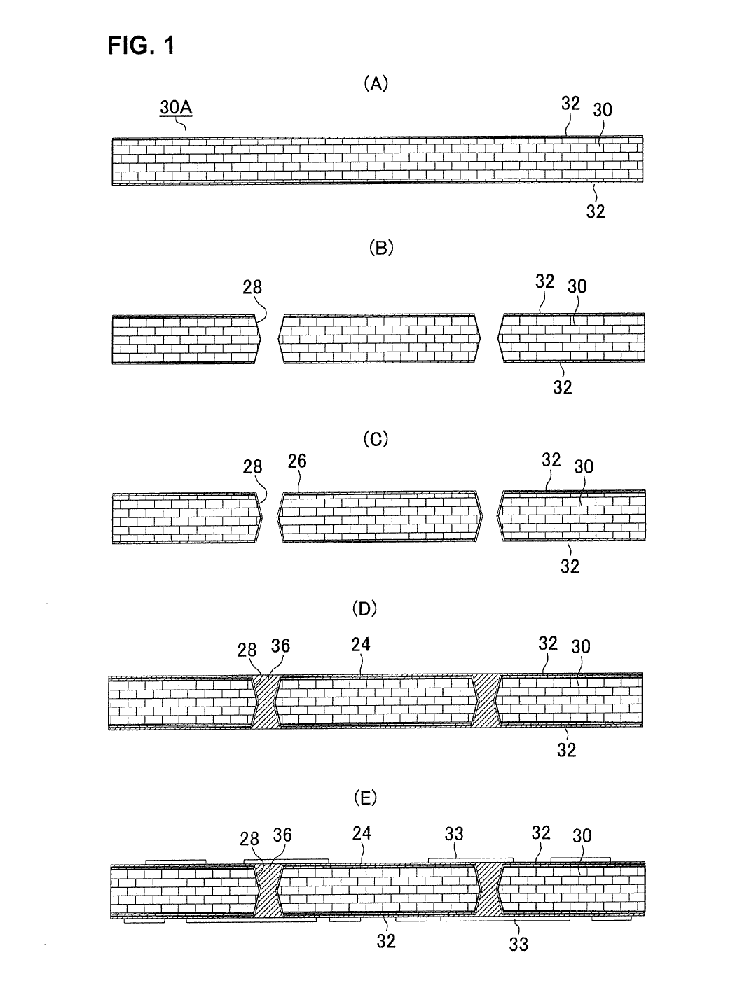

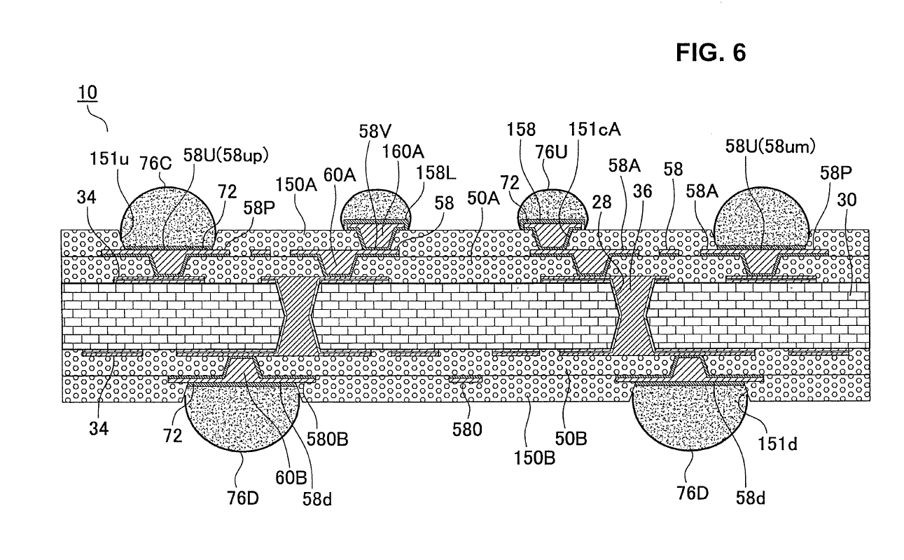

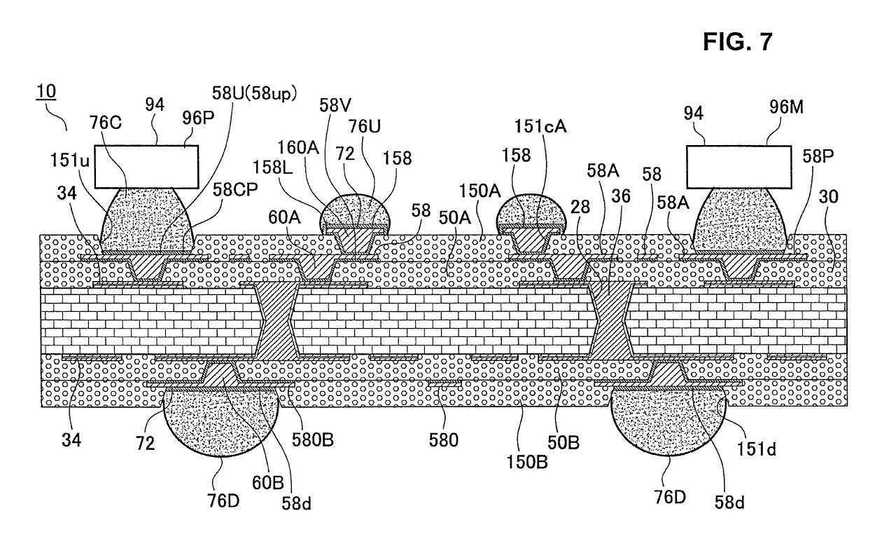

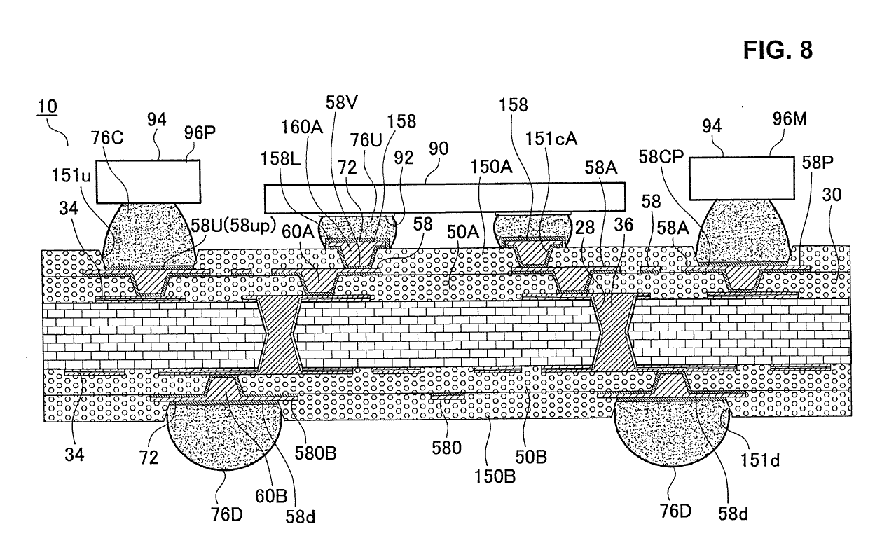

The structure of printed wiring board 10 according to an embodiment of the present invention is described with reference to FIGS. 1˜8. FIG. 6 shows a cross-sectional view of printed wiring board 10. FIG. 7 shows a state in which chip capacitors 94 are mounted on printed wiring board 10 shown in FIG. 6. FIG. 8 shows a state in which IC chip 90 and chip capacitors 94 are mounted on printed wiring board 10. As shown in FIG. 6, printed wiring board 10 has core substrate 30, conductive circuits 34 formed on the upper and lower surfaces of the core substrate, and through-hole conductors 36. Through-hole conductors 36 connect the conductive circuits on the upper surface of core substrate 30 and the conductive circuits on the lower surface. First lower resin insulation layer (50A) is formed on the upper surface (first surface) of core substrate 30, and second lower resin insulation layer (50B) is formed on the lower surface (second surface) of the core substrate. The lower surface of the core substrate is the surface opposite the upper surface of the core substrate. On first lower resin insulation layer (50A), first upper conductive layer 58 is formed, containing multiple first upper conductive circuits (58A), multiple via-conductor pads (58V) and multiple pads (58U) (58up, 58um) for mounting chip capacitors (chip-capacitor pads). First lower via conductors (60A) are formed in first lower resin insulation layer (50A), and the conductive circuits on the upper surface of the core substrate and the first upper conductive layer are connected by first lower via conductors (60A). Second upper conductive layer 580, which contains multiple second upper conductive circuits (580B), is formed on second lower resin insulation layer (50B). In second lower resin insulation layer (50B), second lower via conductors (60B) are formed, and the conductive circuits on the lower surface of the core substrate and the second upper conductive circuits are connected by second lower via conductors (60B).

Upper outermost resin insulation layer (150A) is formed on first lower resin insulation layer (50A) and the first upper conductive layer. Upper outermost resin insulation layer (150A) has via holes (151cA) that partially expose via-conductor pads (58V) and openings (151u) that expose chip-capacitor pads (58U). A circle is preferred as the shape of via-conductor pads (58V), and its diameter is 40 μm˜100 μm. A rectangle is preferred as the shape of chip-capacitor pads (58U), and the length of one side is 0.21 mm˜0.4 mm and the length of the other side is 0.325 mm˜1.305 mm.

Lower outermost resin insulation layer (150B) is formed on second lower resin insulation layer (50B) and second upper conductive layer 580. Lower outermost resin insulation layer (150B) has via holes (151d) which reach second upper conductive circuits (580B). Second upper conductive circuits (580B) exposed through via holes (151d) work as external electrodes to place solder bumps or pins for connection with a motherboard. Solder bumps (76D) or pins are placed on the external electrodes.

Lands (158L) (lands on upper outermost resin insulation layer) are formed on upper outermost resin insulation layer (150A). Lands (158L) and via-conductor pads (58V) are connected by via conductors formed in via holes (151cA). Via conductors include filled vias formed by filling via holes (151c) with conductor and conformal vias formed by covering the inner walls of via holes (151c) with conductor. In FIG. 6, lands (158L) and pads (58V) are connected by via conductors (filled vias) (160A). A land is formed around a via conductor, and the land and the via conductor are directly connected (the land is extended from the via conductor). In FIG. 6, land (158L) is formed around filled via (160A), and land (158L) and filled via (160A) are directly connected. Land (158L) is extended from filled via (160A). Top surfaces of via conductors (160A) and top surfaces of lands (158L), or top surfaces of via conductors (160A), top surfaces of lands (158L) and side surfaces of lands (158L) function as electrodes 158 on which to mount an electronic component such as an IC. Solder bumps (76U) are formed on the electrodes. Solder (76C) is formed on chip-capacitor pads (58U). The solder bumps formed on electrodes are preferred to be Pb-free bumps. In the embodiment, solder bumps are not in contact with a resin layer such as a solder-resist layer, thus allowing an IC chip to be mounted using Pb-free bumps in which cracking tends to occur. Protective films such as OSP or Sn film may be formed on top surfaces of chip-capacitor pads, exposed surfaces of electrodes and top surfaces of external electrodes. If via conductors are filled vias, top surfaces of filled vias and top surfaces of lands are positioned on substantially the same plane.

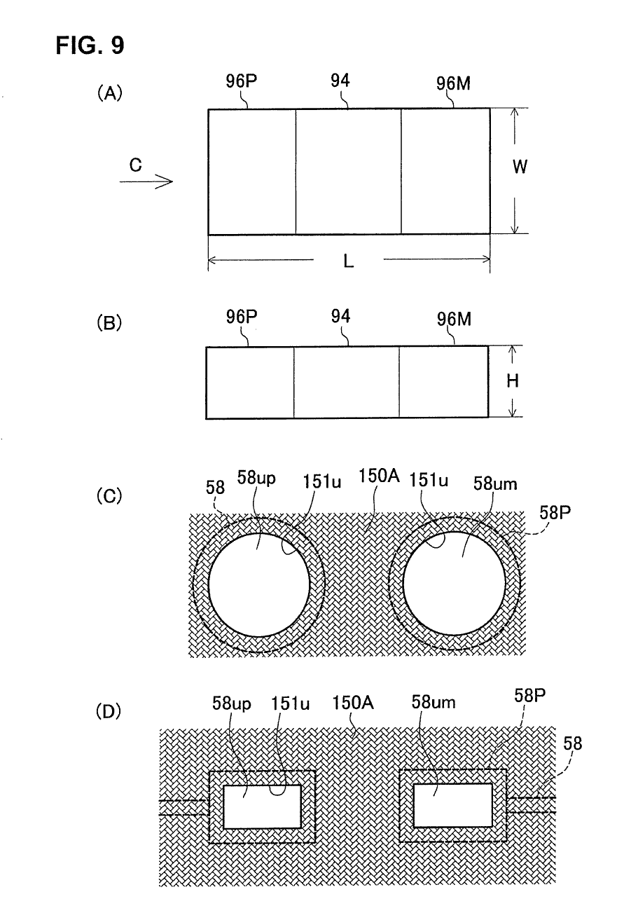

As shown in FIG. 7, chip capacitors 94 are mounted through solder (76C) on chip-capacitor pads (58U). FIG. 9A is a plan view of a chip capacitor and FIG. 9B is a side view. The view of a chip capacitor shown in FIG. 7 is a cross-sectional view obtained by observing the chip capacitor in FIG. 9(A) from direction “C”. Since a chip capacitor has plus terminal (96P) and minus terminal (96M), is made smaller having length L: 0.60 mm˜2.00 mm; width W: 0.30 mm˜1.25 mm; and height H: 0.3 mm˜0.5 mm, and is lightweight, it is difficult to mount it through reflow. FIG. 9(D) is a magnified plan view showing openings (151u) (openings to expose chip-capacitor pads) formed in upper outermost resin insulation layer (150A) and chip-capacitor pads (58U). That view shows an example in which chip-capacitor pads and conductive patterns (58P) are shaped to be rectangular. That is a rectangular example, but chip-capacitor pads and conductive patterns may also be shaped to be circular as shown in FIG. 9(C). Chip-capacitor pads are surrounded with conductor. Conductive pattern (58P) with a predetermined shape is formed with a chip-capacitor pad and conductor surrounding its periphery. The periphery of each conductive pattern is covered with upper outermost resin insulation layer (150A). The conductor surrounding each chip-capacitor pad is covered with upper outermost resin insulation layer (150A). Namely, of a conductive pattern, a chip-capacitor pad is the portion exposed outside through opening (151u). Conductive patterns including chip-capacitor pads are contained in the first upper conductive layer. Openings (151u) are formed by using a laser or through an exposure and development process. Since openings (151u) are formed using light such as laser light, the size of openings is set at a predetermined size. Accordingly, in conductive patterns (58P), the size of the portions which are exposed through openings (151u) is also set at a predetermined size. The size of each chip-capacitor pad (58U) is set at a predetermined size. When chip-capacitor pads are formed by etching the conductor using an etching solution, it is difficult to make uniform the amount to be etched. Namely, when chip-capacitor pads are formed through etching, the size of each chip-capacitor pad tends to vary. Compared with a method for forming chip-capacitor pads through etching, the embodiment method is excellent in controlling the size of chip-capacitor pads. Namely, the difference in solderability of each chip-capacitor pad is smaller in the embodiment than that in Japanese Laid-Open Patent Publication No. 2004-63904. Therefore, a printed wiring board according to the embodiment is preferable for a printed wiring board to mount fine chip capacitors and lightweight chip capacitors. In a printed wiring board according to the embodiment, Manhattan phenomena seldom occur. Openings (151u) are preferred to be formed by a laser, because a laser may be used to form openings (151u) in a greater variety of materials than by using an exposure and development process. Chip-capacitor pads (58U) include plus-terminal pad (58up) for connection with the plus terminal of a chip capacitor and minus-terminal pad (58um). Plus terminal (96P) of a chip capacitor is connected to plus-terminal pad (58up) through solder (76C), and minus terminal (96M) of the chip capacitor is connected to minus-terminal pad (58um) through solder (76C).

As shown in FIG. 8, terminals 92 of IC chip 90 are connected to solder bumps (76U) formed on electrodes 158 exposed from upper outermost resin insulation layer (150A). Top surfaces of electrodes 158 protrude from upper outermost resin insulation layer (150A).

In printed wiring board 10 of the embodiment, there is no solder-resist layer which would expose portions of electrodes 158 and cover electrode peripheries. Solder bumps (76U) are formed on electrodes 158 exposed from upper outermost resin insulation layer (150A).

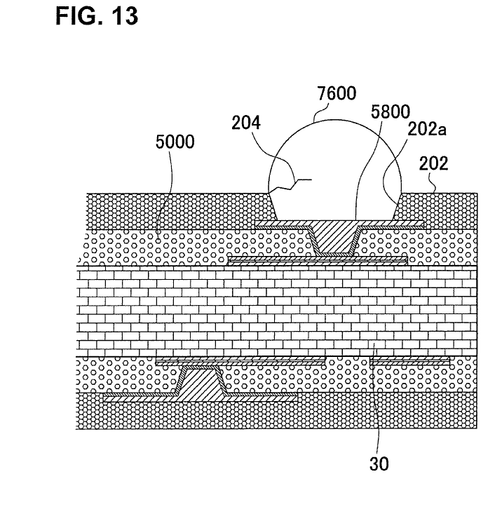

FIG. 13 shows a printed wiring board which has upper outermost resin insulation layer 5000, electrode 5800 formed on upper outermost resin insulation layer 5000, solder-resist layer 202 having opening (202a) which exposes part of the electrode, and solder bump 7600 formed on the electrode exposed through opening (202a) in the solder-resist layer. Solder resist 202 shown in FIG. 13 covers the entire periphery of electrode 5800. In that example, the solder-resist side wall and solder bump 7600 on electrode 5800 are in contact. If the printed wiring board shrinks, stress concentrated on top edges of the opening in the solder resist layer is thought to be exerted on the solder bump on the electrode. Accordingly, in a printed wiring board having the solder-resist layer shown in FIG. 13, it is thought that crack 204 tends to occur in solder bump 7600. An example of cracking is shown in a solder bump in FIG. 13. However, since no such solder-resist layer as shown in FIG. 13 is formed in the embodiment, cracking seldom occurs in solder bump (76U).

In the embodiment, the amount of solder and solderability are substantially the same in chip-capacitor pad (58up) to be connected to a plus terminal of a chip capacitor and chip-capacitor pad (58um) to be connected to a minus terminal of the chip capacitor. Accordingly, compared with a case in which a chip capacitor is mounted on pads (conductive pads) according to conventional art (patent publication (1)), Manhattan phenomena seldom occur. Chip-capacitor pads (58up, 58um) have greater top-surface areas than electrodes 158 for mounting an IC chip. Namely, the amount of solder formed on chip-capacitor pads (58up, 58um) is greater than the amount of solder formed on electrodes 158. In addition, since chip-capacitor pads have a greater size, it is less likely for the solder to come in contact with the top edges of the outermost resin insulation layer. Therefore, even if chip-capacitor pads are not exposed from the outermost resin insulation layer, cracking seldom occurs in solder (76C) on chip-capacitor pads (58up, 58um).

A method for manufacturing printed wiring board 10 in FIG. 6 is described as follows with reference to FIGS. 1˜6.

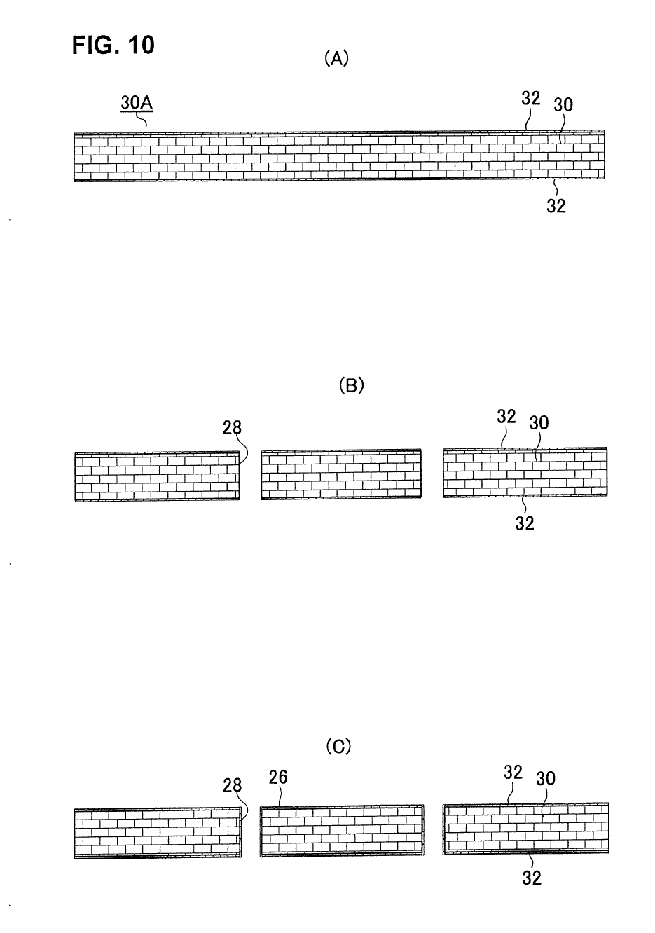

(1) Insulative substrate 30 made of epoxy resin or BT (bismaleimide triazine) resin and a core material such as glass cloth is prepared. Insulative substrate 30 corresponds to the core of a printed wiring board. On both surfaces of insulative substrate 30, 3˜12 μm-thick copper foil 32 is laminated (FIG. 1(A)). The substrate shown in FIG. 1(A) is copper-clad laminate (30A). First, penetrating holes 28 for through-hole conductors are formed by irradiating a laser (FIG. 1(B)). Penetrating holes for through-hole conductors may be shaped straight or in an hourglass shape (FIG. 10(B)). If penetrating holes for through-hole conductors are shaped straight, the penetrating holes are formed by a drill. If the shape is like an hourglass, the holes are formed by irradiating a laser from a first-surface side of an insulative substrate, and then by irradiating a laser from a second-surface side of the insulative substrate.

(2) Electroless copper plating is performed on copper-clad laminate (30A) having penetrating holes for through-hole conductors, and 0.6 μm-thick electroless copper-plated film 26 is formed on the surfaces of copper-clad laminate (30A) and side walls of penetrating holes 28 for through-hole conductors (FIG. 1(C): FIG. 10(C)).

(3) Electrolytic plating is performed and electrolytic copper-plated film 24 is formed in penetrating holes 28 for through-hole conductors and on the surfaces of copper-clad laminate (30A) (FIG. 1(D)). The penetrating holes for through-hole conductors are filled with electrolytic plated film such as copper. It is preferred that penetrating holes for through-hole conductors be in an hourglass shape and that the penetrating holes for through-hole conductors be filled with electrolytic plated film.

(4) Etching resist 33 with a predetermined pattern is formed on electrolytic copper-plated film 24 (FIG. 1(E)).

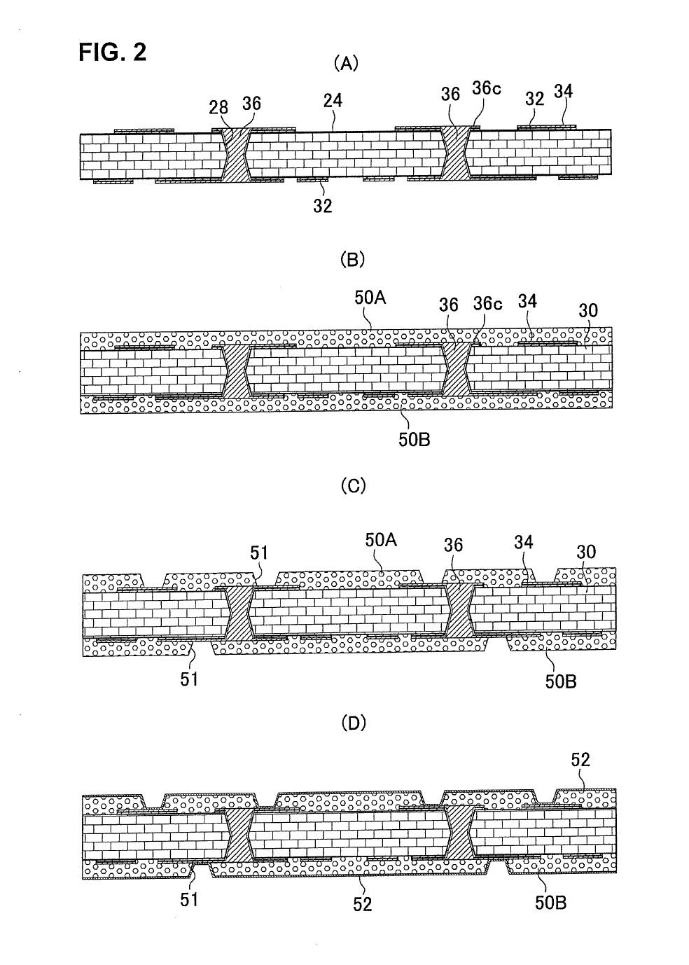

(5) The conductors exposed from etching resist 33 are removed by using an etching solution. Then, etching resist 33 is removed. Conductive circuits 34 including through-hole lands (36c) are formed (FIG. 2(A)).

(6) On the upper surface (first surface) and lower surface (second surface) of substrate 30, resin film for resin insulation layers (brand name ABF-45SH made by Ajinomoto) is laminated and cured. Accordingly, lower resin insulation layers (50A, 50B) are formed (FIG. 2(B)).

(7) Via holes 51 are formed in lower resin insulation layers (50A, 50B) (FIG. 2(C)).

(8) A catalyst is attached to the surfaces of lower resin insulation layers (50A, 50B).

(9) Next, the substrate is immersed in an electroless copper plating solution (Thru-Cup PEA) made by C. Uyemura & Co., Ltd. Electroless copper-plated film 52 is formed on the surfaces of lower resin insulation layers (50A, 50B) including the inner walls of via holes 51 (FIG. 2(D)).

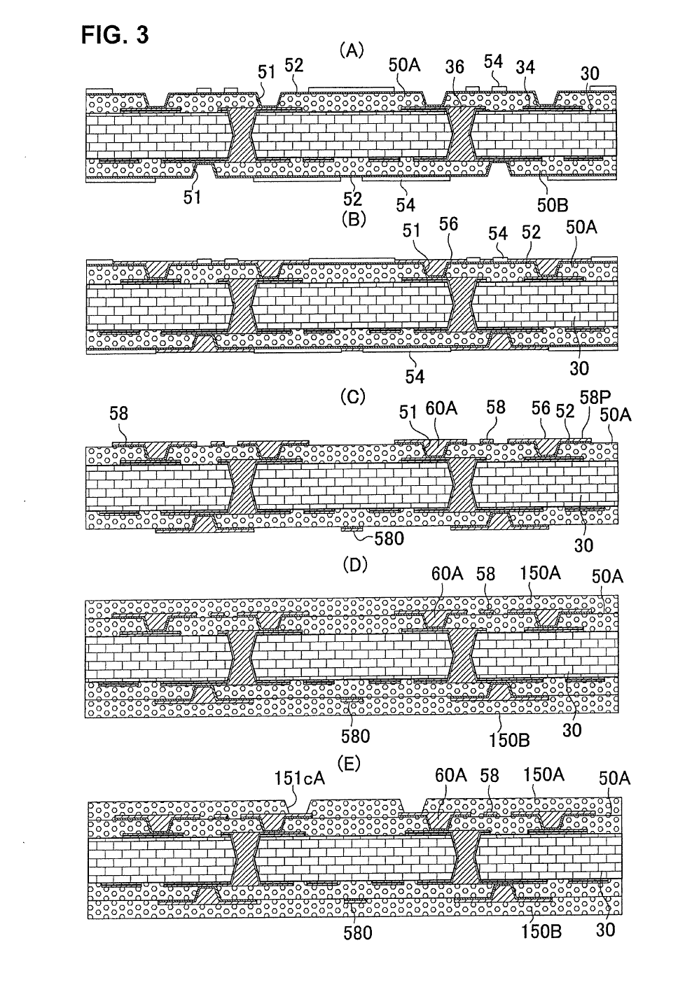

(10) Plating resist 54 with a thickness of 25 μm is formed on electroless copper-plated film 52 (FIG. 3(A)).

(11) Electrolytic plating is performed and electrolytic copper-plated film 56 with a thickness of 15 μm is formed on electroless plated film 52 exposed from plating resist 54 (FIG. 3(B)).

(12) Moreover, electroless plated film exposed by removing plating resist 54 (electroless plated film between portions of electrolytic plated film) is etched away. Conductive layers (58, 580) and via conductors 60 (60A, 60B) are formed (FIG. 3(C)). First upper conductive layer 58 has multiple conductive patterns (58P) and multiple via-conductor pads (58V). Each conductive pattern includes chip-capacitor pad (58U) and conductor surrounding the chip-capacitor pad. Chip-capacitor pads and the conductor surrounding the chip-capacitor pads are formed with the same material.

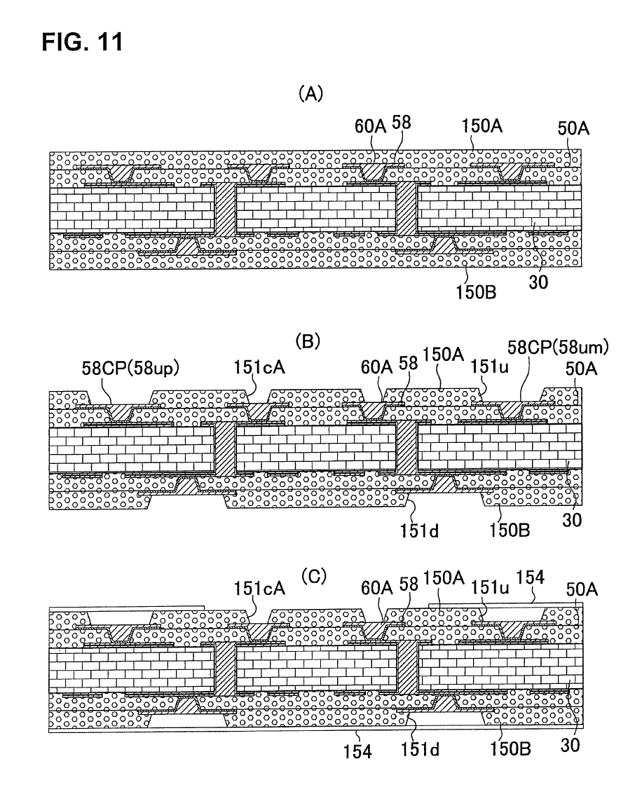

(13) Next, the same as in above step (6), outermost resin insulation layers (150A, 150B) are formed by laminating resin film for resin insulation layers (brand name: ABF-45SH made by Ajinomoto) on lower resin insulation layers (50A, 50B) and then curing the film (FIG. 11(A)).

(14) Using a laser, via holes (151cA) and openings (151u) to expose chip-capacitor pads are formed in upper outermost resin insulation layer (150A). Via holes (151cA) penetrate through upper outermost resin insulation layer (150A) and reach via-conductor pads (58V). Openings (151u) penetrate through upper outermost resin insulation layer (150A) and reach conductive patterns (58P). Chip-capacitor pads (58U) are exposed through openings (151u). In lower outermost resin insulation layer (150B), via holes (151d) are formed reaching second upper conductive circuits (580B). Portions of second upper conductive circuits (580B) exposed through via holes (151d) function as external electrodes (FIG. 11(B)).

(15) By coating film 154 on openings (151u) and via holes (151d), openings (151u) and via holes (151d) are covered with film 154 (FIG. 11(C)).

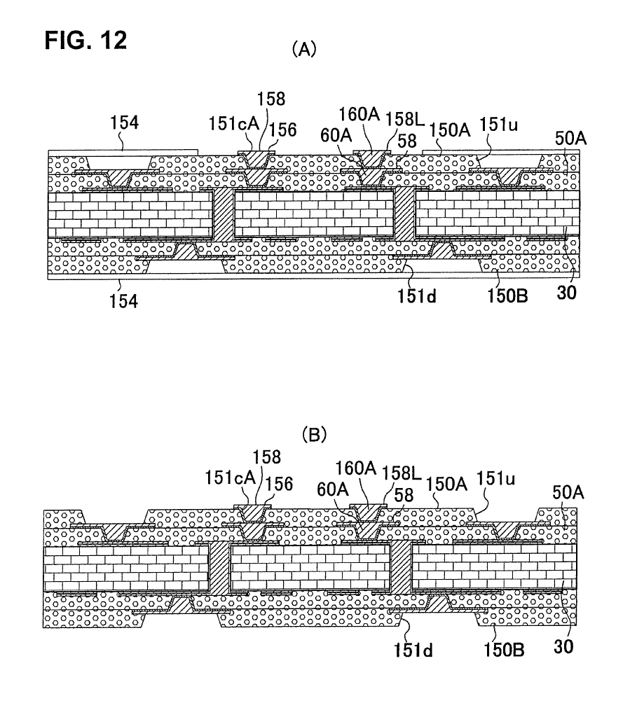

(16) Through the same procedures as in above steps (8)˜(12), lands (158L) are formed on upper outermost resin insulation layer (150A), and via conductors (160A) are formed in via holes (151cA) in upper outermost resin insulation layer (150A). A land surrounds a via conductor, and the via conductor and the land are directly connected. Electrode (158) is formed, being made of a via conductor and a land (FIG. 12(A)). If the via conductor forming an electrode is a filled via, the top surface of the filled via protrudes from the via hole, and the top surface of filled via (160A) and the top surface of land (158L) are positioned on substantially the same plane. The top surface of upper outermost resin insulation layer (150A) is exposed except where the lands are. The conductive circuits formed on the top surface of upper outermost resin insulation layer (150A) are lands (158L) only.

(17) Film 154 is removed and chip-capacitor pads are exposed through openings (151u). Also, external electrodes are exposed through via holes (151d) (FIG. 12(B)). Protective film is formed on top surfaces of electrodes, top surfaces of chip-capacitor pads and top surfaces of external electrodes. As for electrodes, protective film may be formed on their top and side surfaces. Protective film is selected from among OSP (organic surface protection film), Sn film, Ni/Au film, Ni/Pd/Au film and the like. Among those, OSP or Sn film is preferred, because such film forms protective film uniformly on electrodes that protrude from the outermost resin insulation layer and on chip-capacitor pads that are recessed from the outermost resin insulation layer.

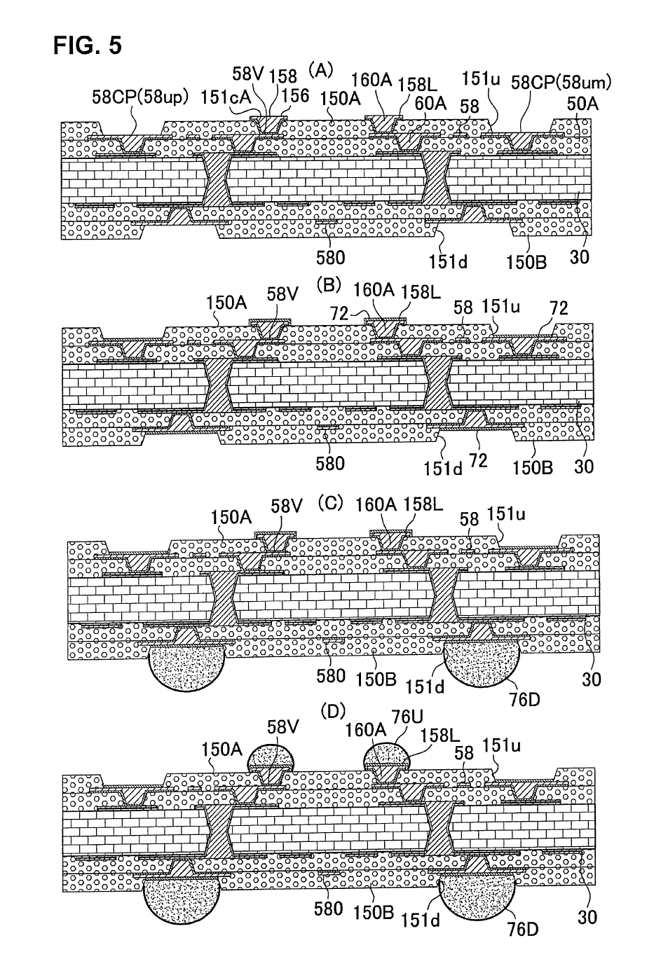

(18) Solder balls are placed on external electrodes and reflowed so that solder bumps (76D) for connection with a motherboard are formed on the external electrodes (FIG. 5(C)).

(19) Solder paste is printed on electrodes and reflowed so that solder bumps (76U) for mounting an IC are formed on the electrodes (FIG. 5(D)).

(20) Solder paste is printed on chip-capacitor pads and reflowed so that solder (76C) for mounting chip capacitors is formed on chip-capacitor pads (FIG. 6).

(21) Plus terminal (96P) and minus terminal (96M) of chip-capacitor 94 are positioned to make contact with solder (76C) and reflowed so that plus terminal (96P) of the chip capacitor is connected to plus-terminal pad (58up) and minus terminal (96M) of the chip capacitor is connected to minus-terminal pad (58um) through solder (76C) (FIG. 7).

(22) Terminals 92 of IC chip 90 are placed on solder bumps (76U) on electrodes 158 and reflowed so that IC chip 90 is mounted (FIG. 8).

### MODIFIED EXAMPLE OF THE EMBODIMENT

A printed wiring board according to a modified example of the embodiment is substantially the same as a printed wiring board according to the embodiment. Using a method for manufacturing a modified example of the embodiment, outermost resin insulation layers (150A, 150B) are formed on a core substrate through the process up to step (13) of the embodiment (FIG. 3(D)). Then, in upper outermost resin insulation layer (150A), via holes (151cA) penetrating through upper outermost resin insulation layer (150A) and reaching via-conductor pads (58V) are formed. At that time, openings penetrating through upper outermost resin insulation layer (150A) and reaching chip-capacitor pads are not formed in upper outermost resin insulation layer (150A); and via holes penetrating through lower outermost resin insulation layer (150B) and reaching second upper conductive circuits (58B) are not formed in lower outermost resin insulation layer (150B), either.

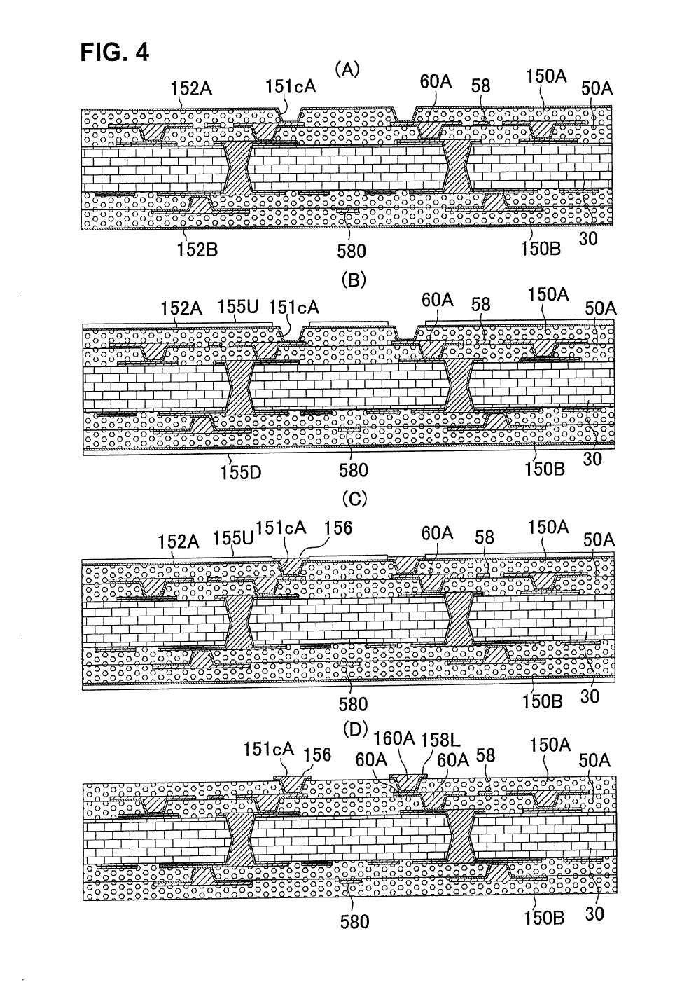

Next, electrodes are formed through the same procedures as in steps (8)˜(12) of the embodiment (FIGS. 4(A)˜4(D)). At that time, electroless copper-plated film (152B) on lower outermost resin insulation layer (150B) is covered with plating resist (155D) while electrolytic plated film is formed (FIGS. 4(B), 4(C)). Electroless copper-plated film (152B) on the lower interlayer resin insulation layer is removed at the same time when electroless copper-plated film (152A) between electrodes is removed.

Then, in upper outermost resin insulation layer (150A), openings (151u) are formed to penetrate through upper outermost resin insulation layer (150A) and reach chip-capacitor pads. Also, in lower outermost resin insulation layer (150B), via holes (151d) are formed to penetrate through lower outermost resin insulation layer (150B) and reach second upper conductive circuits (58B) (FIG. 5(A)).

Next, protective film is formed on top surfaces of electrodes, top surfaces of chip-capacitor pads and top surfaces of external electrodes. Protective film 72 may be formed on the top and side surfaces of electrodes. As for protective film, the same material as that for the embodiment may be used (FIG. 5(B)).

Then, using the same procedures as in steps (18)˜(22) of the embodiment (FIGS. 5(C), 5(D), FIG. 6, FIG. 7), an IC chip and chip capacitors are mounted through solder bumps and solder onto a printed wiring board of the modified example of the embodiment (FIG. 8).

### MODIFIED EXAMPLE (2) OF THE EMBODIMENT

A printed wiring board according to modified example (2) of the embodiment is substantially the same as a printed wiring board according to the embodiment. Using a method for manufacturing modified example (2) of the embodiment, outermost resin insulation layers (150A, 150B) are formed on a core substrate through the process up to step (13) of the embodiment (FIG. 11(A)). Then, using a mask and through exposure and development, via holes penetrating through upper outermost resin insulation layer (150A) and reaching via-conductor pads (58V), and openings reaching chip-capacitor pads are formed in upper outermost resin insulation layer (150A). Also, via holes (151d) penetrating through lower outermost resin insulation layer (150B) and reaching second upper conductive circuits (580B) are formed through exposure and development in lower outermost resin insulation layer (150B).

Then, using the procedures in steps (15)˜(16) of the embodiment, an IC chip and chip capacitors are mounted through solder bumps and solder onto a printed wiring board of modified example (2) of the embodiment (FIG. 8).

Even if penetrating holes for through-hole conductors are shaped straight, a printed wiring board the same as shown in FIG. 6 is formed by a method according to the above embodiment, or the modified example of the embodiment, or modified example (2) of the embodiment.

### EXAMPLE

(1) A copper-clad laminate formed with 0.6 mm-thick glass epoxy resin and 5 μm-thick copper foil is prepared as a starting material (FIG. 1(A)). A laser is irradiated from the upper surface and the lower surface of the core substrate. Penetrating holes 28 for through-hole conductors are formed in an hourglass shape (FIG. 1(B)). Such a penetrating hole is formed with a first opening that gradually becomes narrower from the upper surface of the core substrate toward the lower surface and with a second opening that gradually becomes narrower from the lower surface of the core substrate toward the upper surface. The first opening and the second opening are connected inside the core substrate. In the embodiment, the modified example of the embodiment and modified example (2) of the embodiment, penetrating holes are formed according to the same method as in the example.

(2) By performing electroless copper plating on copper-clad laminate (30A) having penetrating holes for through-hole conductors, 0.6 μm-thick electroless copper-plated film 26 is formed on surfaces of copper-clad laminate (30A) and side walls of penetrating holes 28 for through-hole conductors (FIG. 1(C)).

(3) By performing electrolytic plating, electrolytic copper-plated film 24 is formed in penetrating holes 28 for through-hole conductors and on surfaces of copper-clad laminate (30A) (FIG. 1(D)). Penetrating holes for through-hole conductors are filled with electrolytic copper plating.

(4) Etching resist 33 with a predetermined pattern is formed on electrolytic copper-plated film 24 (FIG. 1(E)).

(5) The conductor exposed from etching resist 33 is removed using an etching solution. After that, etching resist 33 is removed. Conductive circuits 34 including through-hole lands (36c) are formed (FIG. 2(A)).

(6) Resin film for resin insulation layers (brand name: ABF-45SH made by Ajinomoto) is laminated on the upper surface (first surface) and lower surface (second surface) of substrate 30 and cured to form lower resin insulation layers (50A, 50B) (FIG. 2(B)).

(7) Using a CO2 gas laser, via holes 51 are formed in lower resin insulation layers (50A, 50B) (FIG. 2(C)).

(8) A catalyst is attached on lower resin insulation layers (50A, 50B).

(9) Next, the substrate is immersed in an electroless copper plating solution made by C. Uyemura & Co., Ltd. (Thru-Cup PEA). Electroless copper-plated film 52 is formed on surfaces of lower resin insulation layers (50A, 50B) including the inner walls of via holes 51 (FIG. 2(D)).

(10) Plating resist 54 with a thickness of 25 μm is formed on electroless copper-plated film 52 (FIG. 3(A)).

(11) Electrolytic copper-plated film 56 with a thickness of 15 μm is formed through electrolytic plating on electroless copper-plated film 52 exposed from plating resist 54 (FIG. 3(B)).

(12) Furthermore, electroless plated film exposed by removing plating resist 54 (electroless plated film between portions of electrolytic plated film) is etched away. Conductive layers (58, 580) and via conductors 60 are formed (FIG. 3(C)). Conductive layer 58 has multiple conductive patterns (58P) and multiple via-conductor pads (58V). Each conductive pattern includes a chip-capacitor pad and conductor surrounding the chip-capacitor pad. Chip-capacitor pads and the conductor surrounding chip-capacitor pads are made of copper.

(13) Next, the same as in above step (6), resin film for resin insulation layers (brand name: ABF-45SH made by Ajinomoto) is laminated on lower resin insulation layers (50A, 50B) and cured to form outermost resin insulation layers (150A, 150B) (FIG. 3(D)).

(14) Using a CO2 laser, via holes (151cA) reaching via-conductor pads are formed in upper outermost resin insulation layer (150A) (FIG. 3(E)).

(15) A catalyst is attached on surfaces of outermost resin insulation layers (150A, 150B).

(9) Next, the substrate is immersed in an electroless copper plating solution made by C. Uyemura & Co., Ltd. (Thru-Cup PEA). Electroless copper-plated films (152A, 152B) are formed on surfaces of upper outermost resin insulation layer (150A) including the inner walls of via holes (151cA) and lower outermost resin insulation layer (150B) (FIG. 4(A)).

(10) Plating resists 155 (155U, 155D) with a thickness of 25 μm are formed on electroless copper-plated film 152. Plating resist (155U) on upper outermost resin insulation layer (150A) has a predetermined pattern to partially expose electroless copper-plated film 152. Plating resist (155D) on lower outermost resin insulation layer (150B) covers electroless copper-plated film (152B) on lower outermost resin insulation layer (150B) (FIG. 4(B)).

(11) By performing electrolytic plating, electrolytic copper-plated film 156 with a thickness of 15 μm is formed on electroless copper-plated film (152A) exposed from plating resist (154U) (FIG. 4(C)).

(12) Furthermore, electroless plated films 152 (152A, 152B) exposed by removing plating resists 155 are etched away. Electrodes 158 are formed (FIG. 4(D)).

(13) Using a CO2 laser, openings (151u) penetrating through upper outermost resin insulation layer (150A) and reaching conductive patterns are formed in upper outermost resin insulation layer (150A) (FIG. 5(A)). Chip-capacitor pads are shaped to be rectangular, and the size is 0.21×0.4 mm.

(14) Using a CO2 laser, via holes (151d) penetrating through lower outermost resin insulation layer (150B) and reaching second upper conductive circuits (580B) are formed in lower outermost resin insulation layer (150B) (FIG. 5(A)).

(15) OSP 72 is formed on the top and side surfaces of electrodes, top surfaces of chip-capacitor pads and top surfaces of external electrodes (FIG. 5(B)).

(16) Sn—Bi type solder balls are placed on external electrodes and reflowed so that Sn—Bi type solder bumps (76D) are formed on external electrodes (FIG. 5(C)). Sn—Ag type solder paste is printed on chip-capacitor pads and reflowed so that Sn—Ag type solder (76C) is formed on chip-capacitor pads (58um, 58up). Sn—Pb type solder paste is printed on electrodes and reflowed so that Sn—Pb type solder (76U) is formed on electrodes 158 (FIG. 6).

(17) Chip capacitors 74 are placed on chip-capacitor pads (58up, 58um) and reflowed so that chip capacitors (length: 0.6 mm, width: 0.3 mm, height: 0.3 mm) are mounted on chip-capacitor pads (58up, 58um) through solder (76C) (FIG. 7). IC 90 is placed on electrodes (158L) and reflowed so that IC 90 is mounted on electrodes (158L) through solder (76U) (FIG. 8).

Chip capacitors mounted on a surface of a printed wiring board are becoming smaller and more lightweight for higher integration. So-called Manhattan phenomena may occur.

The reasons for Manhattan phenomena to occur are thought to be as follows. Pads are formed using a semi-additive method or a subtractive method through an etching process. When pads are formed through an etching process, it is difficult to unify the etching amount in each pad. Thus, it is difficult to uniformly form a pad to be connected to the plus terminal of a chip capacitor (plus pad) and a pad to be connected to the minus terminal (minus pad). When mounting a chip capacitor, solder is first formed on pads. Next, the plus terminal of the chip capacitor is placed on the solder formed on a plus pad and the minus terminal of the chip capacitor is placed on the solder formed on a minus pad. Then, reflow is performed and the chip capacitor is mounted on pads through solder. If the sizes of the plus pad and the minus pad are different, it is thought that the amount of solder and the solderability will be different in each pad. Because of the difference, such phenomena may occur when only either the plus terminal or the minus terminal of a chip capacitor is connected to a pad while the other is not connected to a pad.

When a chip capacitor is mounted by reflow through solder on the pads exposed from the outermost resin insulation layer, it is thought that the solder wets and spreads to the side surfaces as well as to the top surfaces of pads. If the top and side surfaces of the pads are exposed, it is thought that the height and shape of each pad tend to be different. Thus, it is thought that the wetting and spreading speed of solder is different in each pad. That is also thought to be a reason for Manhattan phenomena.

A printed wiring board according to the first aspect of the present invention has the following: an insulation layer; a conductive layer formed on the insulation layer and including a pad for a via conductor and a pad for mounting a chip capacitor; an outermost resin insulation layer formed on the insulation layer and on the conductive layer and having a via hole that reaches the pad for a via conductor and an opening that exposes the pad for a chip capacitor; an electrode formed with a via conductor that is formed in the via hole and with a land that is extended from the via conductor and is formed on the outermost resin insulation layer; a solder bump formed on the electrode and for mounting an IC; and solder formed on the pad for mounting a chip capacitor.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
an insulation layer;
a conductive layer formed on the insulation layer and including a via conductor pad and a chip capacitor mounting pad;
an outermost resin insulation layer formed on the insulation layer and the conductive layer and having a via hole reaching the via conductor pad and an opening exposing the chip capacitor mounting pad;
an electrode comprising a via conductor portion formed in the via hole in the outermost resin insulation layer and a land portion extending from the via conductor such that the electrode protrudes from a surface of the outermost resin insulation layer;
a solder bump configured to mount an IC and formed on the land portion of the electrode such that the solder bump is positioned at a portion of the electrode protruding from the surface of the outermost resin insulation layer; and
a solder structure configured to mount a chip capacitor and formed on the chip capacitor mounting pad such that the solder structure extends from the chip capacitor mounting pad and projects from the surface of the outermost resin insulation layer.

2. The printed wiring board according to claim 1, wherein the via hole and the opening formed in the outermost resin insulation layer are formed using a laser.

3. The printed wiring board according to claim 1, wherein the via hole and the opening formed in the outermost resin insulation layer are formed through an exposure and development process.

4. The printed wiring board according to claim 1, wherein the opening has a size which is greater than a size of the via hole.

5. The printed wiring board according to claim 1, wherein the surface of the outermost resin insulation layer has no conductive circuit other than the land portion of the electrode formed thereon.

6. The printed wiring board according to claim 1, wherein the surface of the outermost resin insulation layer has no solder-resist layer.

7. The printed wiring board according to claim 1, wherein the chip capacitor mounting pad has a surface area which is larger than a surface area of the electrode.

8. A method of manufacturing a printed wiring board, comprising:
forming on an insulation layer a conductive layer including a via conductor pad and a chip capacitor mounting pad;
forming an outermost resin insulation layer on the insulation layer and the conductive layer;
forming a via hole reaching the via conductor pad through the outermost resin insulation layer;
forming an opening exposing the chip capacitor mounting pad through the outermost resin insulation layer;
forming an electrode comprising a via conductor portion formed in the via hole in the outermost resin insulation layer and a land portion extending from the via conductor such that the electrode protrudes from a surface of the outermost resin insulation layer;
forming on the land portion of the electrode a solder bump configured to mount an IC such that the solder bump is positioned at a portion of the electrode protruding from the surface of the outermost resin insulation layer; and
forming on the chip capacitor mounting pad a solder structure configured to mount a chip capacitor such that the solder structure extends from the chip capacitor mounting pad and projects from the surface of the outermost resin insulation layer.

9. The method of manufacturing a printed wiring board according to claim 8, wherein the forming of the via hole comprises irradiating a laser through the outermost resin insulation layer, and the forming of the opening comprises irradiating a laser through the outermost resin insulation layer.

10. The method of manufacturing a printed wiring board according to claim 8, wherein the forming of the via hole and the forming of the opening comprise carrying out an exposure and development process.

11. The method of manufacturing a printed wiring board according to claim 8, wherein the forming of the opening comprises forming the opening in a size which is greater than a size of the via hole.

12. The method of manufacturing a printed wiring board according to claim 8, wherein no conductive circuit other than the land portion of the electrode is formed on the surface of the outermost resin insulation layer.

13. The method of manufacturing a printed wiring board according to claim 8, wherein no solder-resist layer is formed on the surface of the outermost resin insulation layer.

14. The method of manufacturing a printed wiring board according to claim 8, wherein the forming of the chip capacitor mounting pad comprises forming the chip capacitor mounting pad with a surface area which is larger than a surface area of the electrode.
